(19) United States
(12) Patent Application Publication
(10) Pub. No.: US 2005/0179399 A1
(43) Pub. Date: Aug. 18, 2005

(54) Pixel for an active matrix display

(76) Inventors: Karl Leo, Dresden (DE); Oliver Schneider, Dresden (DE)

Correspondence Address: SUTHERLAND ASBILL & BRENNAN LLP, 999 PEACHTREE STREET, N.E., ATLANTA, GA, 30309, US

(21) Appl. No.: 11/034,097

(22) Filed: Jan. 12, 2005

(30) Foreign Application Priority Data
Jan. 16, 2004 (DE) 10 2004 002 587.8

(51) Int. Cl. G09G 3/10

(52) U.S. Cl. 315/169.3

(57) ABSTRACT

The invention relates to a pixel for an active matrix display comprising an organic light emitting diode (OLED) (19-23) and a driver circuit having a driver transistor that drives the light emitting diode (19-23) and having a capacitor, a current-carrying path of the driver transistor being connected in series with the light emitting diode (19-23) and at least indirectly between two poles of an operating voltage source. A transport layer (20) of the light emitting diode (19-23) is doped resulting in increased electrical conductivity of the transport layer (20) and is electrically connected to the drain contact (15) of the driver transistor.

The invention relates to a pixel for an active matrix display having an organic light emitting diode (OLED) and a driver circuit having a driver transistor that drives the light emitting diode and is connected by its current-carrying path in series with the light emitting diode and at least indirectly between two poles of an operating voltage source, and having a capacitor.

### PRIOR ART

Since the demonstration of efficient components by Tang et al. in 1987 (C. W. Tang et al., Appl. Phys. Lett. 51 (12), 913 (1987)), OLEDs have been promising candidates for the production of large-area displays. An OLED comprises a sequence of thin layers made of organic materials. The layers typically have a thickness in the range of 1 nm to 1 μm. The layers are usually formed either in vacuum by means of vapor deposition or from a solution, for example by means of spin-coating or printing.

Organic light emitting diodes emit light after the injection of charge carriers in the form of electrons from one side and of so-called holes from the other side into organic layers arranged in between. The charge carrier injection is effected when an external voltage is applied, and this is followed by the formation of excitons, i.e. of electro-hole pairs in an active zone, and the radiative recombination of said excitons. The contact connection of the organic layers to an anode (hole-injecting contact) and a cathode (electron-injecting contact) is typically effected by means of at least one transparent electrode, mostly in the form of a transparent oxide, such as indium tin oxide (ITO), for example, and a metallic contact.

Flat displays based on organic light emitting diodes (OLED) can be realized both as a passive matrix and as an active matrix. In the case of passive matrix displays, the image is generated by for example, the lines being successively selected and an image information item selected on the columns being represented. However, such displays are restricted to a size of approximately 100 lines for technical construction reasons.

Displays having a high information content require active driving of the pixels. For this purpose, each pixel is driven by a circuit having transistors, a driver circuit. The transistors are usually designed as thin film transistors (TFT).

Displays of this type are already known with liquid crystal cells as LC-TFT displays (LC—“liquid crystal”). In this case, the reflection or the transmission of an external light source is controlled by the LCDs. Since the LCDs do not emit light themselves, but rather only effect light control, which is generally achieved by means of a voltage-dependent polarization rotation of the light, the LCDs are voltage-controlled, i.e. almost driven without power, with the aid of the driver circuit. For these reasons, a circuit having one transistor and one capacitor generally suffices.

The situation is different in the case of displays having organic light emitting diodes that are driven by means of a current. Since power control has to be effected in this case, a circuit having at least two transistors, i.e. a driving transistor and a driver transistor, and one capacitor is necessary. The transistor is switched by an incoming data signal in order to provide the capacitor with a charge that determines the intended brightness of the OLED. The capacitor then determines the gate potential of the driver transistor, which ultimately sets the current through the organic light emitting diode.

The prior art discloses full color displays such as have been produced by the company Sanyo-Kodak, for example. In this case, active matrices made of polysilicon which contain the respective driver circuit for each pixel are used for OLED displays. The transistors in matrices made of polycrystalline silicon are generally p-channel transistors connected to the anode of the OLED. The layer construction of the OLED begins with the anode arranged on a glass substrate and ends with the cathode; the OLED lies laterally beside the driver transistors and emits through the glass substrate.

The advantage of the matrices made of polycrystalline silicon resides in the relatively high mobility of the charge carriers in this material, which permits high currents for driving the OLED. As has already been shown by J. L. Sanford and F. R. Liebsch in 2003 in SID 03 Digest, page 10 et seq. however, complicated driving circuits having four or more transistors are necessary on account of the typically relatively large inhomogeneities of the polycrystalline silicon. Further disadvantages in the use of matrices made of polycrystalline silicon reside in the complicated fabrication, since a recrystallization step is generally necessary, in the outlay for fabrication on relatively large substrates (which is of great importance for the cost-effective manufacture of displays) and also in the relatively large inhomogeneity of the electrical parameters.

The use of matrices made of amorphous silicon (a-Si) avoids the disadvantages of the matrices made of polycrystalline silicon: matrices made of amorphous silicon can be fabricated significantly more simply, on the one hand, and can be realized more easily on relatively large substrates, on the other hand. Finally, matrices made of amorphous silicon have a significantly better spatial homogeneity of the electrical parameters in comparison with polycrystalline silicon. Generally, active matrices based on amorphous silicon are realized by means of n-channel transistors. p-channel transistors can also be used, in principle, but are not suitable for OLED driving owing to the very low hole mobility in the undoped channel.

Both J.-J. Lih et al., SID 03 Digest, page 14 et seq. 2003 and T. Tsujimura, SID 03 Digest, page 6 et seq. 2003 describe first OLED displays having matrices made of amorphous silicon. The known matrices made of amorphous silicon operate with n-channel transistors. In both cases, the anode of the organic light emitting diodes is connected to the output of a TFT circuit.

Although the use of active matrices made of amorphous silicon has the advantages described, appreciable disadvantages are also associated therewith: on the one hand, a limitation of the currents occurs on account of the generally significantly lower mobilities of the amorphous silicon, which requires highly efficient OLEDs; on the other hand, amorphous silicon degrades under loading, so that burn-in effects and, as a result, inhomogeneities arise. A significant effect in this case is the shift in the threshold voltage Vₜₕ of the transistors owing to ageing.

Simple typical circuits for an arrangement for OLED displays having a matrix made of amorphous silicon generally comprise two n-channel transistors. The first transistor, the so-called driving transistor, is turned on by means of a data signal line and a row select line and charges a capacitor that controls the second transistor, which functions as a driver transistor. If such a very simple two-transistor circuit that can be realized in an efficient manner is connected to the anode of the OLED, then a more precise consideration reveals that this is associated with an appreciable disadvantage: if the driver transistor is intended to be operated in the saturation region, the driving of the gate of the driver transistor demands very high switching potentials (“voltage swings”). The latter cannot be generated by driving circuits using customary CMOS silicon technology. In addition, in the case of this circuitry, the ageing of the OLED and associated voltage changes influence the gate potential of the driver transistor. Since the voltage of the OLED influences the control voltage of the driver transistor in any case during operation, this type of driving turns out to be difficult. A corresponding circuit having the disadvantages mentioned is specified in J.-J. Lih et al., SID 03 Digest, page 14, 2003.

The aforementioned disadvantage with the use of two n-channel transistors and the connection of the driver transistor to the anode can be avoided with the aid of significantly more complicated circuits with a higher number of transistors. J. L. Sanford and F. R. Liebsch, SID 03 Digest, page 10, 2003 discloses a pixel having a circuit and a light emitting unit arranged on the circuit, an n-channel transistor being used as the driver transistor, the anode of the organic light emitting diode being connected to the transistor, and the circuit having four to six transistors for compensation of inhomogeneities. The circuits of differing complexity are intended to compensate for parameter fluctuations and ageing of the light emitting unit by means of more transistors. The more transistors are used in a pixel, however, the more cost-intensive its production becomes since the yield decreases correspondingly. Furthermore, the area available for the driver transistor decreases, which aggravates the problem of ageing.

It is also pointed out that the problem area described holds true in a symmetrical manner if p-channel transistors are used instead of n-channel transistors. In this case, the direct connection of the driver transistor to the cathode has the effect that the OLED voltage has to be concomitantly taken into account in the control voltage during operation.

A further important aspect for the realization of efficient OLED displays is optimization of the area of the OLED. In most OLED displays, the OLED emits through the glass substrate (“bottom emitter”). In this case, the electronics of the pixel that are required for driving are arranged beside the OLED. Consequently, less than half of the area of the pixel remains for the actual light emitting unit of the pixel, namely for the OLED. The smaller the light emitting unit is made in comparison with the pixel, the higher the current density with which the OLED has to be operated. Higher current densities again have a disadvantageous effect on the lifetime.

More suitable is an organic light emitting diode that emits away from the substrate (“top-emitter”), since this can be constructed on the driving circuit and, as a result of this, the pixel area can be used approximately in its entirety for the light emitting unit. T. Tsujimura et al., SID 03, page 6, 2003 describes such an arrangement for displays having a matrix made of amorphous silicon. In this case, the OLED anode contact connects to the driver transistor. Light is emitted through the transparent cathode. This arrangement has the already mentioned disadvantage that the OLED voltage influences the control voltage and the advantage of saturation operation of the driver transistor cannot be utilized. Therefore, the OLED driving current generated by the driver transistor, reacts sensitively to shifts in the threshold voltage (Vₜₕ) and to changes in the organic light emitting diode. Such shifts are unavoidable as the transistors and OLED age.

### THE INVENTION

It is an object of the invention to provide a pixel for an active matrix display having an organic light emitting diode which enables an efficient utilization of the area. Moreover, the intention is to enable the production of the pixel with the aid of the use of cost-effective methods.

According to the invention, this object is achieved for a pixel according to the preamble of claim 1 by virtue of the fact that a transport layer of the light emitting diode, which transport layer is made conductive by means of doping, is electrically connected to the drain contact of the driver transistor.

What is achieved in this way in conjunction with a suitable design of the driver circuit is that the driver transistor can be operated in saturation and is therefore relatively insensitive to ageing processes.

The driver circuit is connected to the organic light emitting diode via the doped transport layer. This prevents a high-impedance contact from being produced on account of a contact metal being connected to an undoped organic layer. The doped transport layer proposed enables the light emitting diode to be adapted to underlying layers in the pixel, as a result of which the production process can be made cost-effective by means of the choice of suitable doping materials and the adaptation that is thereby possible, which enables the use both of n-channel driver transistors (in conjunction with a connection to a cathode of the light emitting diode) and of p-channel driver transistors (in conjunction with the connection to an anode of the light emitting diode).

With the aid of the doping, the conductivity of the conducting transport layer of the organic light emitting diode in the region of the customary operating temperatures is increased by orders of magnitude.

The connection of the doped transport layer to the drain contact of the driver transistor furthermore prevents the gate-source voltage of the driver transistor from being influenced by the voltage across the organic light emitting diode. As a result of this, the following is avoided, namely, variations of parameters of the light emitting diodes or ageing phenomena that lead to an alteration of the voltage across the light emitting diode which will adversely influence the saturation of the driver transistor, so that the current flow through the light emitting diode and ultimately the brightness thereof is thereby kept stable.

Dependent subclaims relate to advantageous refinements of the invention.

By way of example, an n-dopant used may be a molecular dopant having a molecular mass of greater than approximately 200 g/mol. A preferred example is the n-dopant Pyronin D or Leukokristallviollett (A. Werner et al., Appl. Phys. Lett. 82, 4495 (2003)). In an alternative example, an n-doped transport layer is lithium-doped 4,7-diphenyl-1,10-phenanthroline. The molecular mixing ratio for 4,7-diphenyl-1,10-phenanthroline (Bphen):Lithium (Li) lies between approximately 10:1 and approximately 1:1, preferably between approximately 5:1 and approximately 1:1, and particularly preferably is approximately 1:1. Other n-type doping variants may likewise be used. The electron transport layer has a thickness in the range of from approximately 20 nm to approximately 100 nm, preferably approximately 40 nm.

A p-doped transport layer (hole transport layer) is preferably made of starburst 4,4,4-tris(3-methylphenylphenylamino) triphenylamine (m-MTDATA) and is p-doped with a 2,3,5,6-tetrafluoro-7,7,8,8-tetracyano-p-quinodimethane (F₄-TCNQ) dopant that is thermally stable up to approximately 80° C. or a 1,6-diaminopyrene (DAP)-F₄-TCNQ dopant. Other p-type doping variants can be utilized. The mixing ratio lies between approximately 1000:1 and approximately 10:1, preferably between approximately 100:1 and approximately 20:1. The hole transport layer has a thickness in the range of from approximately 30 nm to approximately 300 nm, preferably approximately 100 nm.

One refinement of the invention provides for the doped transport layer to be connected to the drain contact of the driver transistor via a planar electrode. The electrode serves for contact-connection to the drain contact, which can be achieved by conventional means of metallization.

One development of the invention provides for the conductive transport layer to be directly connected to the drain contact of the driver transistor. This is made possible on account of the adaptability of the transport layer by means of doping and constitutes a simplification of the production process owing to the omission of a metallization.

Another refinement of the invention provides for the contact-connection of the drain contact of the driver transistor to be effected by means of a composite layer made of at least one organic material, which is doped, if appropriate, and a metallic component. Such a composite layer has high electrical conductivity and may be produced by means of CO vaporization, by way of example.

In one embodiment of the invention, the electrode (anode/cathode) connected to the driver transistor is designed in such a way that it reflects as efficiently as possible the radiation emitted by the active layers of the OLED. This may be achieved for example by means of a highly reflective material such as silver. The invention affords particular advantages in this connection since highly reflective metals often have a high work function and thus do not produce a good contact particularly with electron-conducting organic layers.

In a further refinement of the invention, the electrode connected to the driver transistor is designed in such a way that it efficiently reflects the radiation emitted by the active layers of the OLED on the basis of a multilayer arrangement. This may be achieved for example by means of a dielectric multilayer. This may be connected with the invention in a particularly efficient fashion since, by way of example, a through-connection through the reflection layers is possible with the aid of the doped organic layers.

In one development of the invention, the electrode connected to the driver transistor is designed in such a way that it efficiently reflects the radiation emitted by the active layers of the OLED by means of a multilayer arrangement. This may be achieved for example with the aid of a dielectric multilayer. This is particularly efficient in connection with the invention since, by way of example, a through-connection through the reflection layers is possible with the aid of the doped organic layers.

In a preferred embodiment of the invention, the electrode connected to the driver transistor is designed in such a way that it reflects the incident light as little as possible (reflection-reducing). This may be achieved for example by means of suitable dielectric layers or organometallic composite layers. Although the efficiency of the organic light emitting diode is generally lowered as a result of this, what is achieved is that externally incident light is not reflected and, as a result of this, the contrast of the OLED display becomes high without using further measures such as, by way of example, polarization filters for increasing the contrast.

The arrangement proposed here can also be generalized to driver circuits having more than two transistors. A refinement of the invention that is very reliable with regard to stability provides for the driver circuit to have four transistors in a current mirror arrangement, where the driver transistor is formed as part of the current mirror arrangement. By means of the current mirror arrangement, a mirror current is set in the driver transistor; and said mirror current, in addition to the measures mentioned above, is extremely independent of the manufacturing tolerance of the components of the pixel, in particular of manufacturing tolerances and ageing phenomena of the light emitting diode.

The current mirror arrangement is formed by four transistors and one capacitor. The circuit arrangement and the transistor type are known in principle, and are described for example in J. L. Sandford, F. R. Libsch, SID 2003, page 10 et seq. Any other current mirror circuit can also be used as an alternative. What is achieved by means of the current mirror arrangement is that the driver transistor is operated very reliably in the saturation region even in the case of shifts in the threshold voltage on account of ageing of the transistor and/or of the organic light emitting diode, with the result that ageing does not lead, or at most leads only to a small extent, to alterations in the brightness of the light emitting diode and thus the light emission of the component.

The invention may also be advantageously developed by virtue of the fact that the light emitting diode is designed as a transparent organic light emitting diode. A fully transparent (>70% transmission) organic light emitting diode has a high light efficiency. Protection of all the organic layers, but in particular of the light emitting layers, against damage to the transparent covering contact is ensured at the same time. In the case of such a transparent OLED, the hole transport layer is p-doped with an organic acceptor material and the electron transport layer is n-doped with a donor material, with dopants having a mass of >200 g/mol. By way of example, it is possible to use the transparent OLEDs described in the patent application DE 102 15 210.

Finally, it is particularly expedient for the driver circuit and the light emitting diode to be applied on a common substrate in such a way that the driver circuit and the light emitting diode are formed on a common substrate, the driver circuit being arranged between the light emitting diode and the common substrate, and the light emitting diode being formed as a top emitter OLED with a light emitting direction directed away from the common substrate.

Consequently, the driving circuit lies below the organic light emitting diode. As a result, it is possible to maximize the area of the pixel and thus to increase the luminosity without increasing the current flow. A pixel configured in this way has a layer construction having a substrate base, the driver circuit arranged thereon and the organic light emitting diode formed thereon. OLEDs that emit away from the substrate (top emitter) are constructed on the driving circuit, so that the pixel area can be used approximately in its entirety for the light emitting unit. Light is emitted through the transparent electrode situated at the top. Such a layer construction is advantageous in terms of production engineering insofar as the application of the driver circuit to the substrate is effected under more drastic conditions, such as at a higher temperature, for example, than the application of the organic light emitting diode. Consequently, the light emitting diode is not exposed to further loadings of further production processes, with the exception of that during its own application. As a top emitter, the light emitting diode extends essentially over the entire basic area of the pixel. This embodiment is possible in a particularly advantageous manner in connection with a two-transistor circuit operated in saturation.

### DRAWING

The invention is explained in more detail below on the basis of exemplary embodiments with reference to a drawing, in which:

FIG. 1 shows a circuit arrangement of a pixel according to a first exemplary embodiment;

FIG. 2 shows a cross section through a pixel according to the first exemplary embodiment in FIG. 1 with a gate situated at the top;

FIG. 3 shows a cross section through a pixel according to a second exemplary embodiment with a gate situated at the bottom;

FIG. 4 shows a circuit arrangement for a pixel with a current mirror arrangement;

FIG. 5 shows a circuit arrangement for a pixel with a current mirror arrangement and only one scan line;

FIG. 6 shows a circuit arrangement for a pixel with two p-channel TFTs;

FIG. 7 shows a cross section through a pixel in which a p-doped transport layer is connected to the drain contact of a p-channel driver transistor; and

FIG. 8 shows a circuit arrangement with three n-channel TFTs, which contains a threshold voltage correction of the driver transistor for better homogeneity of the image represented on a display.

### Exemplary Embodiments

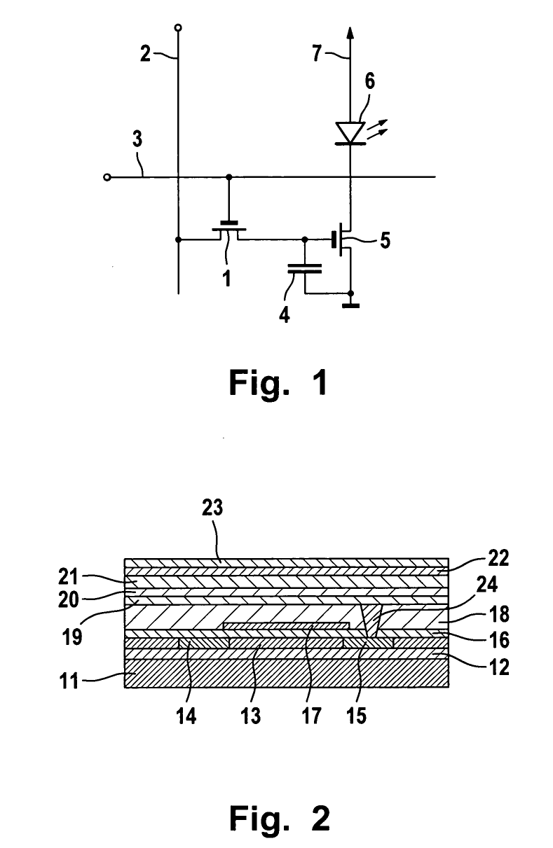

The invention is explained below with reference to FIG. 1 firstly on the basis of an exemplary embodiment—which is particularly relevant in practice—of a pixel for an active matrix display having a circuit having n-channel transistors such as can preferably be realized on the basis of amorphous silicon.

FIG. 1 shows a simplified electrical circuit diagram of a circuit arrangement of a pixel according to a first exemplary embodiment, the circuit comprising two transistors. A first transistor, referred to as driving transistor 1, serves for storing the potential of a data signal line 2, which transistor is turned on by means of a row select line 3 and a capacitor 4 is charged with the potential of the data signal line 2. The capacitor 4 controls a second transistor, the driver transistor 5. The cathode of an organic light emitting diode (OLED) 6 is connected to the drain contact of the driver transistor 5 and receives the operating current from a supply line 7, to which an operating voltage Vdd is applied.

What is achieved with the aid of the circuit arrangement according to FIG. 1, in which a direct connection between the cathode of the OLED and the drain contact of the driver transistor 5 is formed, is that the driver transistor 5 is operated in the saturation region, with the result that possible shifts in the threshold voltage on account of ageing of the driver transistor 5 or of the OLED 6 do not lead, or at most lead only to a small extent, to alterations of brightness in the case of the pixel. The cathode of the OLED 6 is connected to the drain contact of the driver transistor 5 and receives the operating current from the supply line 7. Such an arrangement has the effect that the driver transistor 5 can be operated in the saturation region without the voltage swing of an external driving circuit becoming too large. This can be shown on the basis of the following calculation:

Saturation condition:
V_{tT2}<V_{GS2}<V_{tT2}+V_{DS2}
V_{DATA}=V_{DS1}+V_{GS2}≈V_{GS2}(V_{DS1}≈0)
V_{DD}=V_{DS2}+V_{F}
V_{tT2}<V_{DATA}<V_{tT2}+V_{DS2}
I_{OLED}=0.5k(V_{DATA}−V_{tT2})²

On the basis of the above considerations, a shift in the threshold voltage on account of ageing of the driver transistor 5 cannot lead to alterations of brightness, or can lead to alterations of brightness only to a small extent.

Conversely, contact-connecting the drain contact of the driver transistor 5 to the anode of the OLED would lead to excessive voltage swings which, under specific conditions, may exceed the display supply voltage:

Saturation condition:
V_{tT2}<V_{GS2}<V_{tT2}+V_{DS2}
V_{DATA}=V_{DS1}+V_{F}+V_{GS2}≈V_{F}+V_{GS2}(V_{DS1}≈0)
V_{DD}=V_{DS2}+V_{F}
V_{tT2}+V_{F}<V_{GS2}+V_{F}<V_{tT2}+V_{DS2}+V_{F}
V_{tT2}+V_{F}<V_{DATA}<V_{tT2}+V_{DD}
I_{OLED}=0.5k(V_{DATA}−V_{tT2}−V_{F}(I_{OLED}))²

FIG. 2 shows a cross section of a pixel according to the first exemplary embodiment in FIG. 1 with a gate situated at the top (“top gate”). The construction illustrated comprises one possible technological design of the circuit outlined in FIG. 1 with an organic light emitting diode that emits away from a substrate (“top emitter”).

A circuit made of amorphous silicon is applied on a carrier (substrate) 11 made of glass. An organic light emitting diode is arranged on the circuit. An insulation layer 12 made of SiNₓ is additionally applied on the carrier 11. Arranged on said insulation layer is a thin layer made of intrinsic, amorphous silicon as channel 13 of the transistor, which becomes n-conducting when turned on. A source contact 14 is situated on one side and a drain contact 15 on an opposite side of the channel 13. The source/drain contacts 14, 15 are thin layers made of n-doped silicon which in each case contact-connect the channel 13 situated in between.

A gate contact 17 is applied as “top gate” on a further applied layer made of SiNₓ of a gate insulator 16. The gate 17 is a layer made of a titanium-platinum alloy (TiPt). The gate unit with the gate 17 is coated by a passivation layer 18.

An organic light emitting diode (OLED) with one or a plurality of organic layers is then applied thereon. A cathode 19 made of aluminum is arranged on the passivation layer 18, a doped electron transport layer 20 being applied to said cathode. The electron transport layer 20 is n-doped. It preferably has a thickness of approximately 40 nm and is made of a lithium-doped 4,7-diphenyl-1,10-phenanthroline with 4,7-diphenyl-1,10-phenanthroline (Bphen) lithium (Li) in the molecular mixing ratio of approximately 1:1. Other doping variants are likewise possible.

An emitter layer construction 21 of the organic light emitting diode comprising a plurality of layers is arranged on the electron transport layer 20. The emitter layer construction 21 comprises an electron-side blocking layer made of Bphen having a thickness of approximately 10 nm, above that an approximately 20 nm thick electroluminescent layer made of tris(8-hydroxyquinoline)aluminum (Alq₃), which is mixed with emitter dopants—inter alia with quinacridones—in order to increase the internal quantum efficiency of the light generation, and further a hole-side blocking layer made of N,N-diphenyl-N,N-bis(3-methylphenyl)-(1,1-biphenyl)-4,4-diamine (TPD) having a thickness of approximately 5 nm.

A hole transport layer 22 having a thickness of approximately 100 nm is situated on the emitter layer construction 21, the hole transport layer 22 being p-doped in the case of this exemplary embodiment. The hole transport layer 22 is made of starburst 4,4,4-tris(3-methylphenylphenylamino)triphenyl-amine (m-MTDATA) which is p-doped with a 2,3,5,6-tetrafluoro-7,7,8,8-tetracyano-p-quinodimethane (F₄TCNQ) dopant that is thermally stable up to approximately 80° C. or a 1,6-diaminopyrene (DAP)-F₄-TCNQ dopant.

A semitransparent anode 23 made of indium tin oxide (ITO) is constructed in concluding fashion on the top side, with the result that the emitted light can emerge from the organic layer construction through said anode. The anode 23 is protected from lateral contact with the cathode 19 of the organic light emitting diode by means of a further application, namely insulation layers (not illustrated).

During production, the organic layers are applied in the context of a vapor deposition process in vacuum by means of co-vaporization (in the case of doped layers). In principle, however, the layers may also be applied with the aid of other methods known from the prior art, such as, by way of example, vapor depositing the substances on one another with subsequent, optionally temperature-controlled diffusion of the substances in one another or spinning on the already mixed substances, which can be performed in vacuum. In particular the two blocking layers, the electron-side blocking layer and the hole-side blocking layer, are vapor-deposited in vacuum, and may alternatively also be applied by means of spin-coating.

The driver circuit of the pixel is connected by the drain contact 15 via a plated-through hole 24 directly to the cathode 19 of the organic light emitting diode.

In this case, the plated-through hole 24 passes at one location through the passivation layer 18 and through the gate insulator 16.

It is an advantage of this arrangement that, on account of the direct contact-connection between the cathode 19 and the n-channel 13 via the plated-through hole 24 and the drain contact 15, the driver transistor can be operated in saturation and is therefore insensitive to a shift in the threshold voltage. Furthermore, the direct contact-connection between the output of the transistor and the cathode 19 permits a very simple technical construction.

A prerequisite for the realization is the formation of the organic light emitting diode as a light emitting diode that emits away from the substrate. In this case, there is the fundamental problem that such an OLED is generally significantly less efficient than an organic light emitting diode that emits through the substrate. This problem is solved by means of doping the transport layers, as is described in particular in the patent application DE 101 35 513. As an alternative, it is also possible to use fully transparent organic light emitting diodes, as are disclosed in particular in the patent application DE 102 15 210.

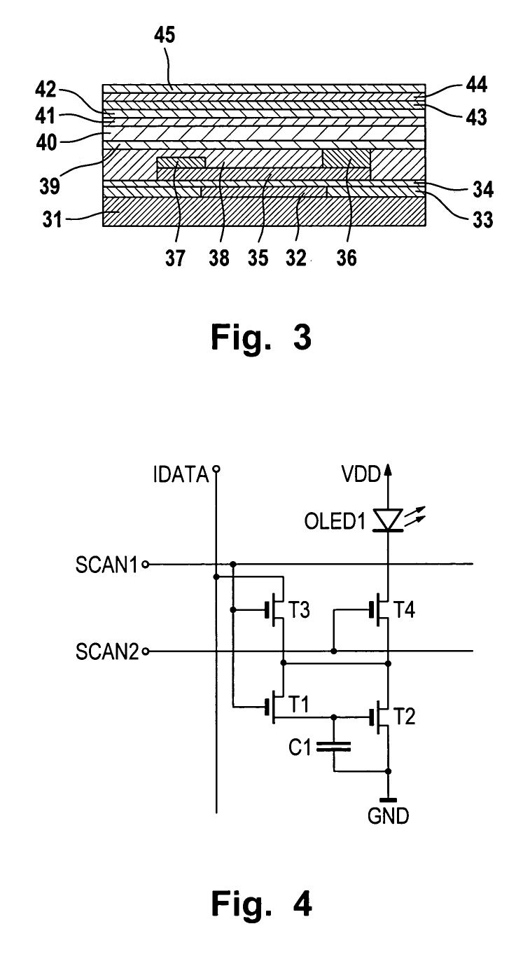

FIG. 3 shows a cross section of a pixel according to a second exemplary embodiment with a gate situated at the bottom.

A gate contact 32 is applied as “bottom gate” directly on a carrier (substrate) 31. The carrier 31 is typically made of glass. The gate contact 32 is made of a titanium-platinum alloy (TiPt). Situated above that is an insulation layer 33 made of SiNₓ, followed by a gate insulation 34 formed as a layer made of SiNₓ.

Arranged thereon is a thin layer made of intrinsic, amorphous silicon as channel 35 of the transistor, which becomes n-conducting when turned on. A drain contact 36 is situated on one side and a source contact 37 on an opposite side of the channel 35. The source/drain contacts 36, 37 are thin layers made of aluminum which in each case contact-connect the channel 35 situated in between. Source/drain regions adjoining the source/drain contact 36, 37 are made of n-doped silicon.

An organic light emitting diode (OLED) having one or a plurality of organic layers is applied above over an insulation layer 38, which is again made of SiNₓ. The bottommost layer of the OLED is a cathode 39 made of aluminum, to which a doped electron transport layer 40 is applied. The electron transport layer 40 is n-doped. It has a thickness of approximately 40 nm and is made of lithium-doped 4,7-diphenyl-1,10-phenanthroline with 4,7-diphenyl-1,10-phenanthroline (Bphen):lithium (Li) in the molecular mixing ratio of approximately 1:1.

An emitter layer construction comprising a plurality of layers is arranged on the electron transport layer 40. The emitter layer construction comprises an electron-side blocking layer 41 made of Bphen having a thickness of approximately 10 nm, above that an approximately 20 nm thick electroluminescent layer 42 made of tris(8-hydroxyquinoleine)aluminum (Alq₃), which is mixed with emitter dopants in order to increase the internal quantum efficiency of the light generation, and further a hole-side blocking layer 43 made of N,N-diphenyl-N,N-bis(3-methylphenyl)-(1,1biphenyl)-4,4-diamine (TPD) having a thickness of approximately 5 nm.

A hole transport layer 44 having a thickness of approximately 100 nm is situated on the emitter layer construction, the hole transport layer 44 being p-doped in the case of this exemplary embodiment. The hole transport layer 44 is made of starburst 4,4,4-tris-(3-methylphenylphenylamino)triphenyl-amine (m-MTDATA) which is p-doped with a 2,3,5,6-tetrafluoro-7,7,8,8-tetracyano-p-quinodimethane (F₄TCNQ) dopant that is thermally stable up to approximately 80° C. or a 1,6-diaminopyrene (DAP)-F₄-TCNQ dopant.

A semitransparent anode 45 made of indium tin oxide (ITO) is applied in a concluding fashion on the top side, with the result that the emitted light can emerge from the organic layer construction of the OLED through said anode.

FIG. 4 shows a simplified electrical circuit diagram of a driver circuit for a pixel. The driver circuit comprises a current mirror arrangement having four n-channel transistors T1, T2, T3, T4 and a capacitor C. The transistors T1 and T3 are turned on by means of the row line SCAN 1. Together with T1, via the transistor T3, the capacitor C is charged by the data line. After said capacitor has been charged, the current flows from the data line through T2. The transistor T4 is turned on by SCAN 2, while SCAN 1 is switched off. Under the control of the voltage across the capacitance (capacitor C), the transistor T2 then sets the same (mirror) current through the OLED.

This type of arrangement of a driver circuit with a current mirror likewise has the effect that the driver transistor—namely the transistor connected to the capacitor by its gate contact—is operated in the saturation region, so that possible shifts in the threshold voltage on account of ageing of the driver transistor and/or the light emitting diode do not lead, or at most lead only to a small extent, to alterations of brightness. In this case, the driver transistor T2 is indirectly connected to the positive pole V_{DD} of the operating voltage source, i.e. the supply line, and thus indirectly connected between the poles of the operating voltage source, in that the transistor T4 is located between the positive pole V_{DD} and the driver transistor T2. The OLED (OLED1 in FIG. 3) nevertheless remains connected in series with the current-carrying path of the driver transistor T2.

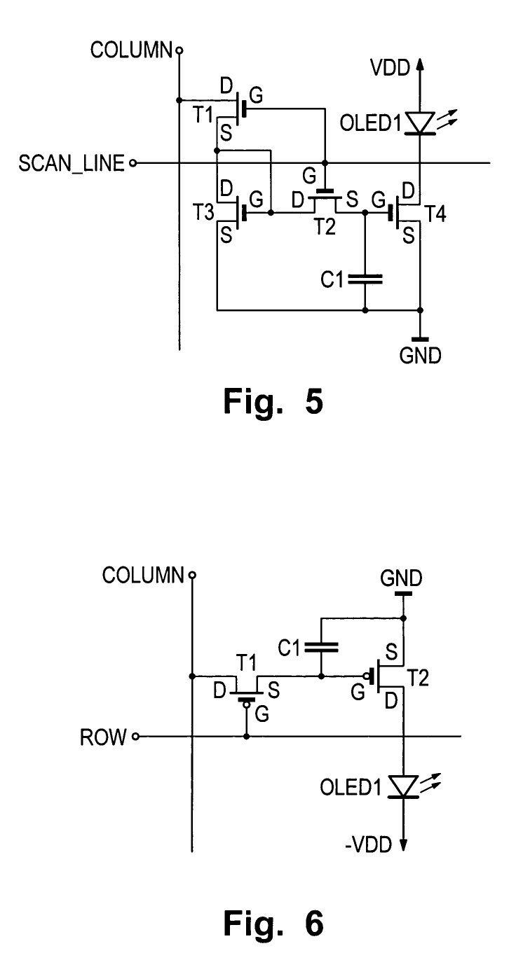

FIG. 5 shows another embodiment of a current mirror arrangement, which uses only one scan line. A precise knowledge of the parameters of the transistors T3 and T4 is a prerequisite here since, in this case, the current to be set does not flow through the driver transistor T2 of the OLED, but rather is formed by way of the ratio of the two transistors.

FIG. 6 shows a circuit embodiment of a 2-TFT circuit with p-channel transistors, a p-doped transport layer of the anode of the OLED being connected to the drain contact of the driver transistor.

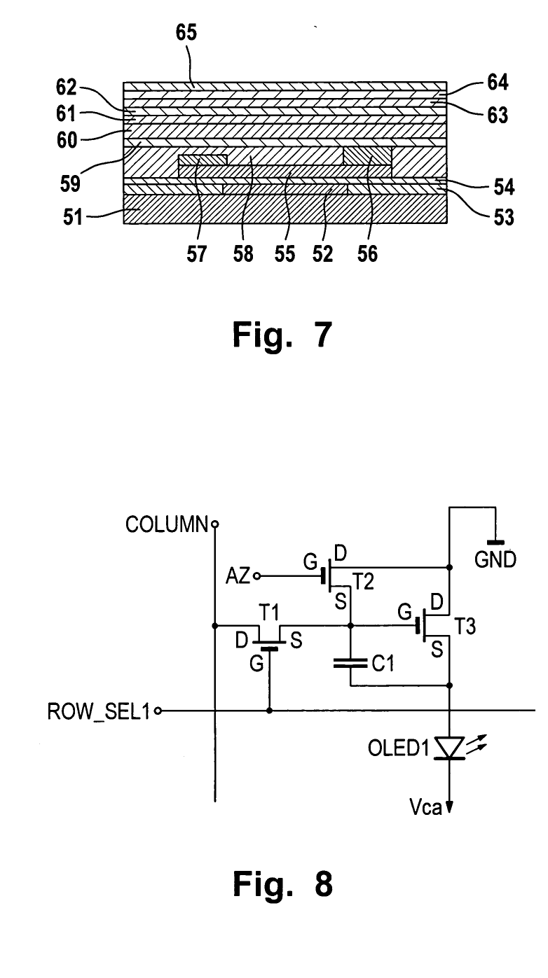

FIG. 7 shows a cross section of a pixel with a p-channel transistor with a gate contact situated at the bottom and an OLED in which the anode is connected to the driver transistor.

A gate contact 52 is applied as “bottom gate” directly on the carrier (substrate) 51. The carrier 51 is typically made of glass and the gate 2 is made of a titanium-platinum alloy (TiPt). Situated above that is an insulation layer 53 made of SiNₓ, followed by a gate insulation 54 formed as a layer made of SiNₓ.

Arranged thereon is a thin layer made of intrinsic silicon as channel 55 of the transistor, which becomes p-conducting when turned on. A drain contact 56 is situated on one side and a source contact 57 on an opposite side of the channel 55. The source/drain contact 56, 57 are thin layers made of aluminum which in each case contact-connect the channel 55 situated in between. The source/drain regions adjoining the source/drain contacts 56, 57 are made of p-doped silicon.

An organic light emitting diode (OLED) having one or a plurality of organic layers is applied above over an insulation layer 58, which is again made of SiNₓ. The bottommost layer of the OLED is an anode 59 made of aluminum, to which a doped hole transport layer 60 is applied. The hole transport layer 60 is p-doped. It has a thickness of approximately 100 nm and is made of starburst 4,4,4-tris(3-methylphenylphenylamino)-triphenyl-amine (m-MTDATA) which is p-doped with a 2,3,5,6-tetrafluoro-7,7,8,8-tetracyano-p-quinodimethane (F₄TCNQ) dopant that is thermally stable up to approximately 80° C. or a 1,6-diaminopyrene (DAP)-F₄-TCNQ dopant.

An emitter layer construction made of a plurality of layers is arranged on the hole transport layer 60. The emitter layer construction comprises a hole-side blocking layer 61 made of N,N-diphenyl-N,N-bis(3-methylphenyl)-(1,1-biphenyl)-4,4-diamine (TPD) having a thickness of approximately 5 nm. This is followed by an approximately 20 nm thick electroluminescent layer 62 made of tris(8-hydroxyquinoline) aluminum (Alq₃), which is mixed with emitter dopants in order to increase the internal quantum efficiency of the light generation. An electron-side blocking layer 63 made of Bphen having a thickness of approximately 10 nm is then arranged thereon.

An electron transport layer 64 having a thickness of approximately 40 nm is situated on the emitter layer construction, the electron transport layer 64 being n-doped in the case of this exemplary embodiment. The electron transport layer 64 is made of a lithium-doped 4,7-diphenyl-1-10-phenanthroline with 4,7-diphenyl-1,10-phenanthroline (Bphen) lithium (Li) in the molecular mixing ratio of approximately 1:1.

A semitransparent cathode 65 made of indium tin oxide (ITO) is applied as the last layer on the top side of the OLED, with the result that the emitted light can emerge from the organic layer construction of the OLED through said cathode.

FIG. 8 shows a circuit arrangement in which a threshold voltage compensation of the driver transistor is performed. In order to represent a new image on the display, a common cathode terminal of the OLED Vca has to be brought to a high positive potential, relative to GND, for a short time in order to completely discharge the OLEDs driven in the reverse direction. Afterwards, a gate terminal of a transistor T2, designated by AZ in FIG. 8, is brought to a positive potential and, at the same time, the voltage Vca is brought to a slightly negative value. The consequence of this is that the voltage on a storage capacitor C1 is set to approximately the threshold voltage of the driver transistor. If, via a transistor T1, the latter is then connected to the data line, then this voltage is present there, too, and only the actual Vdata voltage has to be added. Once new values have been written to all the pixels, the voltage Vca is set to the normal operating potential again and the OLED emits light proportionally to the set voltage Vdata.

The features of the invention which are disclosed in the above description, the claims and the drawing may be of importance both individually and in any desired combination for the realization of the invention in its various embodiments.

### List of Reference Symbols

1 Driving transistor
2 Data signal line
3 Row select line
4 Capacitor
5 Driver transistor
6 Organic light emitting diode (OLED)
7 Supply line
11,31,51 Carrier (substrate)
12,38,58 Insulation layer
13,35,55 Channel in driver circuit
14,37,57 Source
15,36,56 Drain
16,34,54 Gate insulation
17,32,52 Gate
18 Passivation layer
19,39 Cathode
20,40,64 Doped electron transport layer
21,42,62 Emitter layer
22,44,60 Doped hole transport layer
23,45 Semitransparent anode
24 Plated-through hole
41,63 Electron-side blocking layer
42,61 Hole-side blocking layer
59 Anode
65 Semitransparent cathode

1. A pixel for an active matrix display comprising an organic light emitting diode (OLED) and a driver circuit having a driver transistor that drives the light emitting diode and having a capacitor, a current-carrying path of the driver transistor being connected in series with the light emitting diode and at least indirectly between two poles of an operating voltage source, wherein a transport layer of the light emitting diode is doped resulting in increased electrical conductivity of the transport layer and is electrically connected to the drain contact of the driver transistor.

2. The pixel as claimed in claim 1, wherein the transport layer is connected to the drain contact of the driver transistor via a planar electrode.

3. The pixel as claimed in claim 1, wherein the transport layer is directly connected to the drain contact of the driver transistor.

4. The pixel as claimed in claim 1, wherein the driver circuit comprises a further transistor formed as a driving transistor.

5. The pixel as claimed in claim 1, wherein a further transport layer of the light emitting diode is doped resulting in increased electrical conductivity of the further transport layer.

6. The pixel as claimed in claim 1, wherein the transport layer or the further transport layer of the light emitting diode is n-doped with an n-type dopant.

7. The pixel as claimed in claim 6, wherein the n-type dopant is a molecular dopant having a molecular mass of greater than approximately 200 g/mol.

8. The pixel as claimed in claim 6, wherein the n-type dopant is pyronin B, leuco crystal violet or the leuco base of a different cationic dye.

9. The pixel as claimed in claim 6, wherein the n-doped transport layer or the n-doped further transport layer is formed from lithium-doped 4,7-diphenyl-1,10-phenanthroline, a molecular mixing ratio of 4,7-diphenyl-1,10-phenanthroline (Bphen): lithium (Li) lying between approximately 10:1 and approximately 1:3.

10. The pixel as claimed in claim 6, wherein the n-doped transport layer or the n-doped further transport layer is formed from lithium-doped 4,7-diphenyl-1,10-phenanthroline, a molecular mixing ratio of 4,7-diphenyl-1,10-phenanthroline (Bphen): lithium (Li) lying between approximately 5:1 and approximately 1:2.

11. The pixel as claimed in claim 6, wherein the n-doped transport layer or the n-doped further transport layer is formed from lithium-doped 4,7-diphenyl-1,10-phenanthroline, a molecular mixing ratio of 4,7-diphenyl-1,10-phenanthroline (Bphen): lithium (Li) being approximately 1:1.

12. The pixel as claimed in claim 1, wherein the transport layer or the further transport layer of the light emitting diode is p-doped with an organic acceptor material.

13. The pixel as claimed in claim 12, wherein the p-doped transport layer or the p-doped further transport layer is made of starburst 4,4,4-tris (3-methylphenylphenylamino) triphenyl-amine (mMTDATA) and is p-doped with a 2,3,5,6-tetrafluoro-7,7,8,8-tetracyano-p-quinodimethane (F₄-TCNQ) dopant that is thermally stable up to approximately 80° C. or a 1,6-diaminopyrene (DAP)-F₄-TCNQ dopant.

14. The pixel as claimed in claim 12, wherein the p-doped transport layer or the p-doped further transport layer is made of starburst 4,4,4-tris (3-methylphenylphenylamino) triphenyl-amine (mMTDATA) and is p-doped with a 2,3,5,6-tetrafluoro-7,7,8,8-tetracyano-p-quinodimethane (F₄-TCNQ) dopant that is thermally stable up to approximately 80° C. or a 1,6-diaminopyrene (DAP)-F₄-TCNQ dopant in a mixing ratio in the range of from approximately 1000:1 to approximately 10:1.

15. The pixel as claimed in claim 12, wherein the p-doped transport layer or the p-doped further transport layer is made of starburst 4,4,4 tris (3-methylphenylphenylamino) triphenyl-amine (m-MTDATA) and is p-doped with a 2,3,5,6-tetrafluoro-7,7,8,8-tetracyano-p-quinodimethane (F₄-TCNQ) dopant that is thermally stable up to approximately 80° C. or a 1,6-diaminopyrene (DAP)-F₄-TCNQ dopant in a mixing ratio in the range of from approximately 100:1 to approximately 20:1.

16. The pixel as claimed in claim 1, wherein the driver transistor is an n-channel transistor, the light emitting diode is connected between the drain contact of the driver transistor and a positive pole of the operating voltage source, the driver transistor is arranged on a side facing a cathode of the light emitting diode of the light emitting diode, and the capacitor is connected to a gate contact and a source contact of the driver transistor.

17. The pixel as claimed in claim 1, wherein the driver transistor is a p-channel transistor, the light emitting diode is connected between the drain contact of the driver transistor and a negative pole of the operating voltage source, the driver transistor is arranged on a side facing an anode of the light emitting diode, and the capacitor is connected to a gate contact and a source contact of the driver transistor.

18. The pixel as claimed in claim 1, wherein the driver circuit has three transistors and is embodied in threshold voltage compensating fashion.

19. The pixel as claimed in claim 1, wherein the driver circuit has four transistors in a current mirror arrangement, the driver transistor being formed as part of the current mirror arrangement.

20. The pixel as claimed in claim 1, wherein the transistors of the driver circuit are formed as thin film transistors.

21. The pixel as claimed in claim 1, wherein the light emitting diode (19-23; 39-45; 59-65) is a transparent organic light emitting diode (TOLED).

22. The pixel as claimed in claim 1, wherein the driver circuit and the light emitting diode are formed on a common substrate the driver circuit being arranged between the light emitting diode and the common substrate, and the light emitting diode being formed as a top emitter OLED with a light emitting direction directed away from the common substrate.

23. The pixel as claimed in claim 1, wherein the drain contact of the driver transistor is contact-connected by means of an organometallic composite layer.

24. The pixel as claimed in claim 23, wherein the composite layer is electrically doped by means of admixture of one or more substances.

25. The pixel as claimed in claim 1, wherein at least one reflection-increasing layer is arranged between the driver circuit and the light emitting diode.

26. The pixel as claimed in claim 25, wherein the at least one reflection-increasing layer is made of one or more metals.

27. The pixel as claimed in claim 25, wherein the at least one reflection-increasing layer is made of one or more dielectric materials.

28. The pixel as claimed in claim 1, wherein at least one reflection-reducing layer is arranged between the driver circuit and the light emitting diode.

29. The pixel as claimed in claim 28, wherein the at least one reflecting-reducing layer is an organometallic composite layer.

30. The pixel as claimed in claim 28, wherein the at least one reflection-reducing layer is made of one or more dielectric materials.
